(19) United States
(12) Patent Application Publication
(10) Pub. No.: US 2018/0373608 A1
(43) Pub. Date: Dec. 27, 2018

(54) PHASE COMPENSATION METHOD AND ASSOCIATED PHASE-LOCKED LOOP MODULE

(71) Applicant: MStar Semiconductor, Inc., Hsinchu Hsien (TW)

(72) Inventors: Ting-Nan CHO, Hsinchu Hsien (TW); Kai-Wen CHENG, Hsinchu Hsien (TW); Tai-Lai TUNG, Hsinchu Hsien (TW)

(21) Appl. No.: 15/786,925

(22) Filed: Oct. 18, 2017

(30) Foreign Application Priority Data
Jun. 23, 2017 (TW) 106121046

(51) Int. Cl. G06F 11/30; G06F 1/04; H03L 7/099; G06F 17/10

(52) U.S. Cl. CPC G06F 11/3041; G06F 17/10; H03L 7/099; G06F 1/04

(57) ABSTRACT

A phase compensation method applied to a phase-locked loop (PLL) module of a communication device includes determining to output one of a maximum likelihood (ML) phase to an oscillator of the PLL module and a data-aided (DA) phase error to a filter of the PLL module according to an input signal. The ML phase is a phase generated from estimating known data in the input signal by using a ML method, and the DA phase error is a phase error generate from estimating the known data in the input signal by using a DA method.

This application claims the benefit of Taiwan application Serial No. 106121046, filed on Jun. 23, 2017, the subject matter of which is incorporated herein by reference.

### BACKGROUND OF THE INVENTION

### Field of the Invention

The invention relates in general to a phase compensation method and an associated phase-locked loop (PLL) module, and more particularly, to a phase compensation method capable of adjusting a method for estimating phase error of unknown data according to channel quality, and associated phase error estimation method and PLL module.

### Description of the Related Art

A phase-locked loop (PLL) circuit is for generating a periodic output signal, which is expected to have a fixed phase relationship with a periodic input signal. PLL circuits are extensively applied in various circuit systems, for example but not limited to, clock and data recovery circuits, transceivers and frequency synthesizers in wireless communication systems.

FIG. 1 shows a schematic diagram of a PLL circuit 100 in a prior art. The PLL circuit 10 is for calibrating a phase error between an input signal IN and a reference signal (not shown in FIG. 1). As shown in FIG. 1, the PLL circuit 10 includes a multiplier 100, a phase error detecting unit 102, a filter 104, an oscillator 106 and a maximum likelihood circuit 108. The multiplier 100 adjusts the phase of the input signal IN according to a phase compensation signal PC generated by the oscillator 106 to generate a compensated signal CIN to the phase error detecting unit 102. The phase error detecting unit 102 calculates a phase error ϕ between the compensated input signal CIN and a reference signal (not shown), and outputs the phase error ϕ to the filter 104. The filter 104 generates a compensation phase \hat{ϕ} to the oscillator 106 according to the phase error ϕ to adjust the phase compensation signal PC. Using the loop formed by the multiplier 100, the phase error detecting unit 102, the filter 104 and the oscillator 106, the PLL circuit 10 may calibrate the phase error ϕ between the compensated input signal CIN and the reference signal.

In FIG. 1, the maximum likelihood (ML) circuit 108 uses ML to estimate the phase of known data in the input signal IN to generate a ML phase ϕ_{ES}_{_}_{ML}, which is inputted into the oscillator 106 to serve as an initial value for the PLL 10 to calibrate the phase Φ of unknown data in the input signal IN, so as to accelerate the calibration speed. However, when channel quality (e.g., the signal-to-noise ratio (SNR)) is unsatisfactory, ML phase ϕ_{ES}_{_}_{ML} greatly deviates from the actual phase of known data, contrarily significantly slowing down the calibration speed of the PLL circuit 10.

### SUMMARY OF THE INVENTION

To solve the foregoing issues, the present invention provides a phase compensation method capable of adjusting a method for estimating a phase error of unknown data according to channel quality, and associated phase estimation method and phase-locked loop (PLL) module.

According to an aspect of the present invention, the present invention discloses a phase compensation method applied to PLL module of a communication device. The phase compensation method includes determining to output one of a maximum likelihood (ML) phase to an oscillator to the PLL module and a data-aided (DA) phase error to a filter of the PLL according to an input signal. The ML phase is a phase generated from estimating known data in the input signal by using a ML method. The DA phase error is a phase error generating from estimating the known data in the input signal by using a DA method.

According to another aspect of the present invention, the present invention discloses a PLL module applied to a communication device. The PLL module includes: a multiplier, multiplying an input signal by a phase compensation signal to generate a compensated input signal; a phase error detecting unit, detecting a phase error between the compensated input signal and a reference clock signal; a filter, generating a compensation phase according to the phase error; an oscillator, generating the phase compensation signal according to the compensation phase; a ML circuit, estimating the phase of known data in the input signal by a maximum likelihood method to generate a maximum likelihood phase; a DA circuit, estimating a phase error of the known data in the input signal by a DA method to generate a DA phase error; a multiplexer, receiving the ML phase and receiving the DA phase error from the DA circuit, outputting the ML phase to the oscillator or the DA phase error to the filter according to a control signal; and a monitoring unit, generating the control signal according to the input signal.

The above and other aspects of the invention will become better understood with regard to the following detailed description of the non-limiting embodiments. The following description is made with reference to the accompanying drawings.

### BRIEF DESCRIPTION OF THE DRAWINGS

FIG. 1 is a schematic diagram of a conventional phase-locked loop (PLL) module;

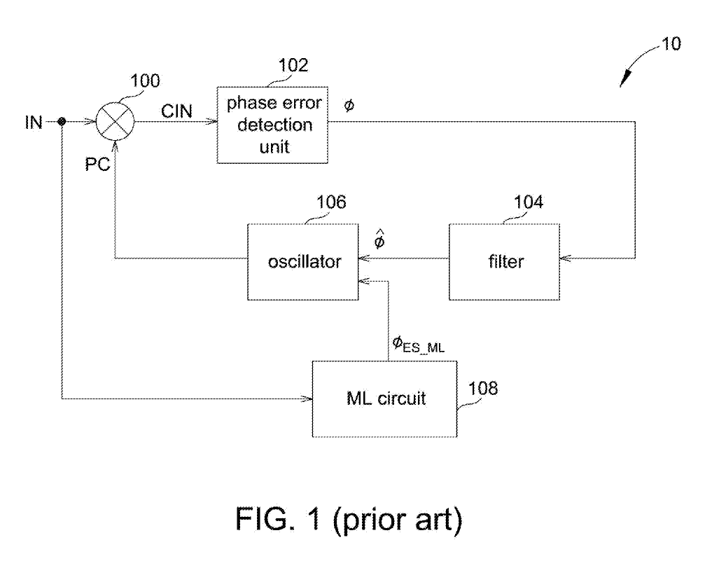

FIG. 2 is a schematic diagram of a PLL module according to an embodiment of the present invention;

FIG. 3 is a flowchart according to an embodiment of the present invention; and

FIG. 4 is a schematic diagram of a signal frame.

### DETAILED DESCRIPTION OF THE INVENTION

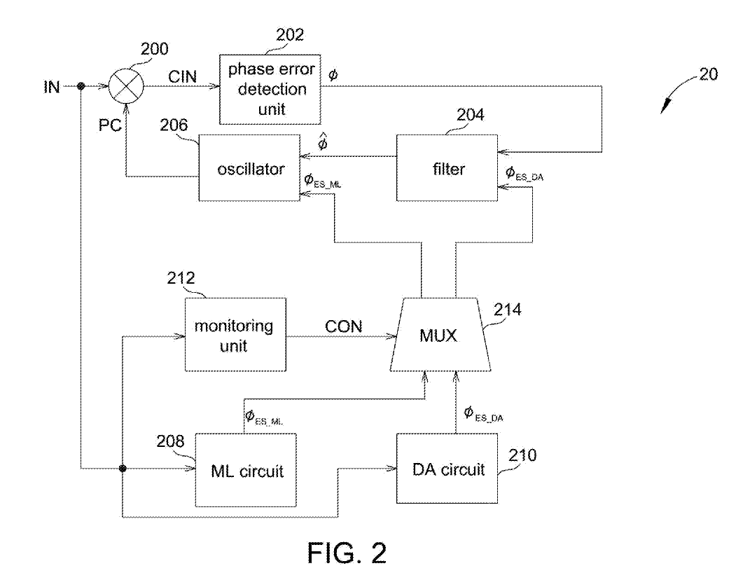

FIG. 2 shows a schematic diagram of a phase-locked loop (PLL) module 200 according to an embodiment of the present invention. The PLL module 20 may be disposed in a communication device to correct a phase error ϕ of an input signal IN. The communication device may be, for example but not limited to, a smart phone, a tablet computer, a laptop computer, and a set-top box (STB). As shown in FIG. 2, the PLL module 20 includes a multiplier 200, a phase error detecting unit 202, a filter 204, an oscillator 206, a maximum likelihood (ML) circuit 208, a data-aided (DA) circuit 210, a monitoring circuit 212 and a multiplexer (MUX) 214. Operation details of the multiplier 200, the phase error detecting unit 202, the filter 204, the oscillator 206 and the ML circuit 208 in the PLL module 200 are identical to those of the multiplier 100, the phase error detecting unit 102, the filter 104, the oscillator 106 and the ML circuit 108 in the PLL circuit 100, and shall be omitted for brevity.

The ML circuit 208 estimates the phase of known data in the input signal IN by a ML method to generate a ML phase ϕ_{ES}_{_}_{ML} and outputs the ML phase ϕ_{ES}_{_}_{ML} to the multiplexer 214. In one embodiment, how the ML circuit 208 calculates the ML phase ϕ_{ES}_{_}_{ML} may be represented by an equation below:

$${φ}_{{ES}_{—} ML} = {tan}^{- 1} \{ \frac{Im ( {\sum }_{i}^{G} {y}_{i} \cdot {m}_{i}^{*} )}{Re ( {\sum }_{i}^{G} {y}_{i} \cdot {m}_{i}^{*} )} \} \qquad ( 1 )$$

In equation (1), tan⁻¹( ) is an arctangent function, Im( ) is a function for obtaining an imaginary part of a complex number, Re( ) is a function for obtaining a real part of a complex number, G is the number of symbols in known data, yᵢ may be represented as mᵢe^{jθ}+nᵢ, mᵢ is the i^{th} symbol in the known data, nᵢ is the complex Gaussian noise of the i^{th} symbol, and θ is the phase shift. Details for implementing the ML circuit 208 based on equation (1) are generally known to one person skilled in the art, and shall be omitted for brevity.

The DA circuit 210 estimates the phase error ϕ of the known data in the input signal IN by a DA method to generate a DA phase error ϕ_{ES}_{_}_{DA}, and outputs the DA phase error ϕ_{ES}_{_}_{DA} to the multiplexer 214. In one embodiment, how the ML circuit 208 calculates the DA phase error ϕ_{ES}_{_}_{DA} may be represented by an equation below:

ϕ_{ES}_{_}_{DA}=Im(yᵢ·mᵢ*) (2)

In equation (2), Im( ) is a function for obtaining an imaginary part of a complex number, yᵢ may be represented as mᵢe^{jθ}+nᵢ, mᵢ is the i^{th} symbol in the known data, nᵢ is the complex Gaussian noise of the i^{th} symbol, and θ is the phase shift. It is known from equation (2) that, the DA circuit 210 calculates the DA phase error ϕ_{ES}_{_}_{DA} of each symbol in the known data. Details for implementing the DA circuit 210 based on equation (2) are generally known to one person skilled in the art, and shall be omitted for brevity.

The monitoring circuit 212 generates a control signal CON according to the input signal IN to control the multiplexer 214 to output the ML phase ϕ_{ES}_{_}_{ML} to the oscillator 206 or the DA phase error ϕ_{ES}_{_}_{DA} to the filter 204, so as to accelerate the calibration speed of the PLL module 20. In this embodiment, the monitoring circuit 212 is implemented by a processor.

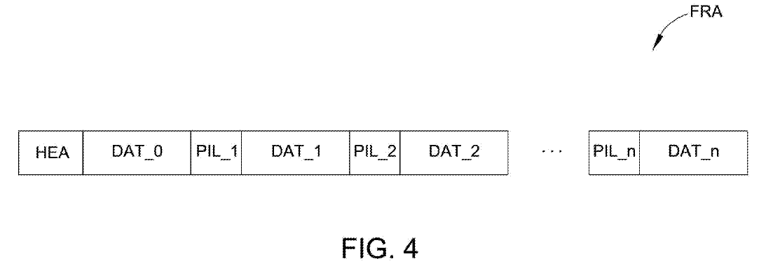

FIG. 4 shows a schematic diagram of a signal frame FRA in the input signal IN. The signal frame FRA includes a header sub-frame HEA, a plurality of pilot sub-frames PIL_1 to PIL_n, a data sub-frame DAT_0 corresponding to the header sub-frame HEA, and data sub-frames DAT_1 to DAT_n respectively corresponding to the pilot sub-frames PIL_1 to PIL_n. The header sub-frame HEA and the pilot sub-frames PIL_1 to PIL_n are known data, and the symbol length of the header sub-frame HEA is greater than the symbol length of the pilot sub-frames PIL_1 to PIL_n. For example, when the wireless communication device operates in Digital Video Broadcasting Satellite Second-Generation (DVB-S2), the header sub-frame includes 90 symbols and the pilot sub-frame includes 36 symbols.

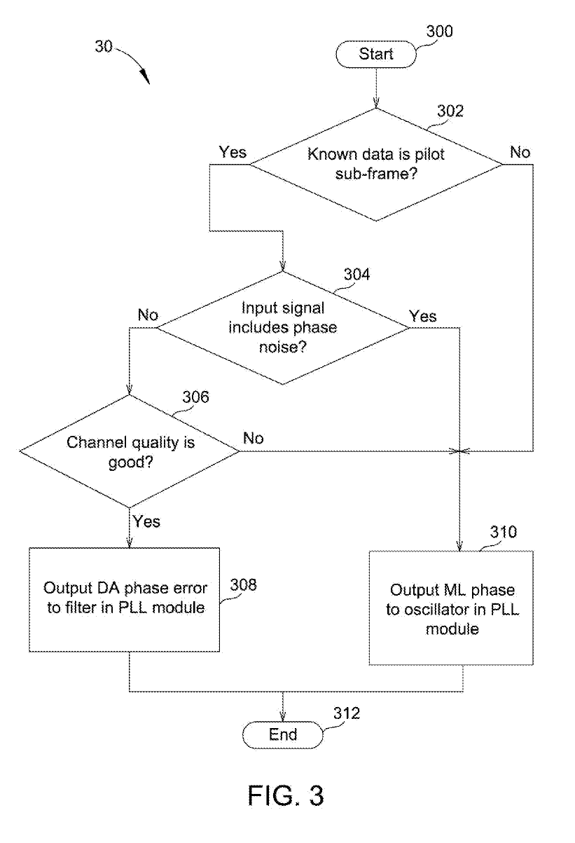

FIG. 3 shows a flowchart of a phase compensation method 30 performed by the monitoring unit 212 according to an embodiment of the present invention. After receiving the input signal IN, the monitoring unit 212 first determines whether the known data in the input signal IN is a pilot sub-frame (step 302). If the known data in the input signal IN is not a pilot sub-frame (i.e., the known data in the input signal IN is a header sub-frame), the monitoring unit 212 controls the multiplexer 214 by a control signal CON to output the ML phase ϕ_{ES}_{_}_{ML} of the header sub-frame to the oscillator 206, so as to cause the oscillator 206 to generate the phase compensation signal PC according to the ML phase ϕ_{ES}_{_}_{ML} (step 310). This is because the Applicant discovered that, as the header sub-frame has a larger number of symbols, the ML phase ϕ_{ES}_{_}_{ML} of the header sub-frame may approach the phase of subsequent unknown data (e.g. the data sub-frame DAT_0). In other words, when the known data in the input signal IN is the header sub-frame HEA, the PLL module 20 corrects the phase error ϕ of the data sub-frame DAT_0 according to the ML phase ϕ_{ES}_{_}_{ML} of the header sub-frame HEA.

If the known data in the input signal IN is a pilot sub-frame, the monitoring unit 212 may further determine whether the input signal IN includes a phase noise (step 304). If the input signal IN includes a phase noise, the monitoring unit 212 controls the multiplexer 214 by a control signal CON to output the ML phase ϕ_{ES}_{_}_{ML} of the pilot sub-frame to the oscillator 206, so as to cause the oscillator 206 to generate the phase compensation signal PC according to ML phase ϕ_{ES}_{_}_{ML} (step 310). In other words, when the known data in the input signal IN is, e.g., the pilot sub-frame PIL_1, and the input signal includes a phase noise, the PLL module 20 calibrates the phase error ϕ of the data sub-frame DATA_1 according to the ML phase ϕ_{ES}_{_}_{ML} of the pilot sub-frame PIL_1. This is because the Applicant discovered that, when the input signal IN includes a phase noise, it means that it is very probable that the phase of the input signal is deviated from a predetermined value. In this situation, if the DA phase error ϕ_{ES}_{_}_{DA} is outputted to the filter 204 when the input signal IN includes a phase noise, the calibration speed of the PLL module 20 may be contrarily reduced. Therefore, when it is determined that the input signal IN includes a phase noise, the monitoring unit 212 adjusts the control signal CON to control the multiplexer 214 to output the ML phase ϕ_{ES}_{_}_{ML} to the oscillator 206, so as to enhance the performance of the PLL module 20.

In one embodiment, when the monitoring unit 212 detects that the phase noise in the input signal exceeds a phase noise threshold, the monitoring unit 212 determines that the input signal IN includes a phase noise.

If the input signal IN does not include a phase noise, the monitoring unit 212 further determines whether the channel quality of the input signal IN is good (step 306). If the channel quality of the input signal IN is good, the monitoring unit 212 controls the multiplexer 214 by a control signal CON to output the ML phase ϕ_{ES}_{_}_{ML} of the pilot sub-frame to the oscillator 206, so as to cause the oscillator 206 to generate the phase compensation signal PC according to the ML error ϕ_{ES}_{_}_{ML} (step 310). If the channel quality of the input signal IN is poor, the monitoring unit 212 controls the multiplexer 214 by a control signal CON to output the DA phase error ϕ_{ES}_{_}_{DA} of the pilot sub-frame to the filter 204, so as to cause the filter 204 to generate the compensated phase \hat{ϕ} according to the DA phase error ϕ_{ES}_{_}_{DA} (step 308).

In other words, when the known data in the input signal IN is, e.g., the pilot sub-frame PIL_2, the input signal IN does not include a phase noise and the channel quality of the input signal IN is good, the PLL module 20 calibrates the phase error ϕ of the data sub-frame DATA_2 according to the ML phase ϕ_{ES}_{_}_{ML} of the pilot sub-frame PIL_2; when the known data in the input signal IN is, e.g., the pilot sub-frame PIL_3, the input signal IN does not include a phase noise and the signal quality of the input signal is poor, the PLL module 20 calibrates the phase error ϕ of the data sub-frame DAT_3 according to the DA phase error ϕ_{ES}_{_}_{DA} of the pilot sub-frame PIL_3. This is because the Applicant discovered that, outputting the DA phase error ϕ_{ES}_{_}_{DA} to the filter 204 instead of outputting the ML phase ϕ_{ES}_{_}_{ML} to the oscillator 206 enhances the performance of the PLL module 20 when the channel quality is not good.

In one embodiment, when the monitoring unit 212 detects that the SNR of the input signal IN is greater than an SNR threshold, the monitoring unit 212 determines that the channel quality of the input signal IN is good.

In conclusion, according to the type of known data, whether the input signal includes a phase noise, and/or the channel quality, the monitoring unit controls the multiplexer to output the ML phase to the oscillator or to output the DA phase error to the filter, so as to accelerate the calibration speed of the PLL module.

While the invention has been described by way of example and in terms of the embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A phase compensation method, applied to a phase-locked loop (PLL) module of a communication device, comprising:
determining, according to an input signal, to output one of a maximum likelihood (ML) phase to an oscillator of the PLL module and a data-aided (DA) phase error to a filter of the PLL module;
wherein, the ML phase is a phase generated from estimating known data in the input signal by a ML method, and the DA phase error is a phase error generated from estimating the known data in the input signal by a DA method.

2. The phase compensation method according to claim 1, wherein the step of determining to output one of the ML phase to the oscillator of the PLL module and the DA phase error to the filter of the PLL module comprises:
determining whether a signal-to-noise ratio (SNR) of the input signal is smaller than an SNR threshold; and
outputting the DA phase error to the filter when the SNR of the input signal is smaller than the SNR threshold.

3. The phase compensation method according to claim 2, wherein the step of determining to output one of the ML phase to the oscillator of the PLL module and the DA phase error to the filter of the PLL module further comprises:
outputting the ML phase to the oscillator when the SNR of the input signal is not smaller than the SNR threshold.

4. The phase compensation method according to claim 2, further comprising:
determining whether a phase noise of the input signal is smaller than a phase noise threshold; and
determining whether the SNR of the input signal is smaller than the SNR threshold when the phase noise of the input signal is smaller than the phase noise threshold.

5. The phase compensation method according to claim 4, further comprising:
outputting the ML phase to the oscillator when the phase noise of the input signal is not smaller than the phase noise threshold.

6. The phase compensation method according to claim 4, further comprising:
determining whether the known data in the input signal is a pilot sub-frame; and
determining whether the phase noise of the input signal is greater than the phase noise threshold when the known data is the pilot sub-frame.

7. The phase compensation method according to claim 6, further comprising:
outputting the ML phase to the oscillator when the known data is not the pilot sub-frame.

8. A phase-locked loop (PLL) module, applied to a communication device, comprising:
a multiplexer, multiplying an input signal by a phase compensation signal to generate a compensated input signal;
a phase error detecting unit, detecting a phase error between the compensated input signal and a reference clock signal;
a filter, generating a compensation phase according to the phase error;
an oscillator, generating the phase compensation signal according to the compensation phase;
a maximum likelihood (ML) circuit, estimating a phase of known data in the input signal by a ML method to generate a ML phase;
a data-aided (DA) circuit, estimating a phase error of the known data in the input signal to generate a DA phase error;
a multiplexer, receiving the ML phase from the ML circuit, and receiving the DA phase error from the DA circuit; and
a monitoring circuit, generating a control signal to the multiplexer according to the input signal to control the multiplexer to output one of the ML phase to the oscillator and the DA phase error to the filter.

9. The PLL module according to claim 8, wherein the monitoring unit determines whether a signal-to-noise ratio (SNR) of the input signal is smaller than an SNR threshold, and, according to a determination result indicating that the SNR is smaller than the SNR threshold, generates the control signal to cause the multiplexer to output the DA phase error to the filter, so as to cause the filter to generate the compensation phase further according to the DA phase error.

10. The PLL module according to claim 9, wherein the monitoring unit, according to an determination result indicating that the SNR is not smaller than the SNR threshold, generates the control signal to cause the multiplexer to output the ML phase to the oscillator, so as to cause the oscillator to generate the phase compensation signal further according to the ML phase.

11. The PLL module according to claim 9, wherein the monitoring unit determines whether a phase noise of the input signal is smaller than a phase noise threshold, and, according to a determination result indicating that the phase error of the input signal is smaller than the phase error threshold, determines whether the SNR of the input signal is smaller than the SNR threshold.

12. The PLL module according to claim 11, wherein the monitoring unit, according to a determination result indicating that the phase noise is not smaller than the phase noise threshold, generates the control signal to cause the multiplexer to output the ML phase to the oscillator, so as to cause the oscillator to generate the phase compensation signal further according to the ML phase.

13. The PLL module according to claim 11, wherein the monitoring unit further determines whether the known data in the input signal is a pilot sub-frame, and, according to a determination result indicating that the known data in the input signal is the pilot sub-frame, determines whether the phase noise of the input signal is greater than the phase noise threshold.

14. The PLL module according to claim 13, wherein the monitoring unit, according to a determination result indicating that the known data is not the pilot sub-frame, generates the control signal to cause the multiplexer to output the ML phase to the oscillator, so as to cause the oscillator to generate the phase compensation signal further according to the ML phase.
